(19) United States
(12) Patent Application Publication
(10) Pub. No.: US 2008/0010019 A1
(43) Pub. Date: Jan. 10, 2008

(54) High speed spectrum analyzer

(76) Inventor: Richard A. Thomas, Miami, FL (US)

Correspondence Address: MCDERMOTT, WILL & EMERY, 4370 LA JOLLA VILLAGE DRIVE, SUITE 700, SAN DIEGO, CA, 92122, US

(21) Appl. No.: 11/825,523

(22) Filed: Jul. 6, 2007

Related U.S. Application Data
(60) Provisional application No. 60/819,251, filed on Jul. 6, 2006.

(51) Int. Cl. G01R 23/16; G06F 19/00

(52) U.S. Cl. 702/1; 702/57; 702/66; 702/75; 702/76; 702/127; 702/189; 356/300; 356/326

(57) ABSTRACT

The invention provides a device for analyzing the spectral content of a sample in a sequential manner at high speed.

This application claims the benefit of priority of U.S. Provisional application Ser. No. 60/819,251, filed Jul. 6, 2006, the entire contents of which are incorporated herein by reference.

### BACKGROUND OF THE INVENTION

The present invention relates generally to instrumentation and more specifically to spectrum analyzers such as flow cytometers.

A Flow Cytometer is a device that flows a particle through a sensing zone where the particle is normally excited by a beam of light that then causes the particle to fluoresce and or scatter light. The particles pass through the sensing zone, and the emitted light is then separated by filters into portions of the electromagnetic (EM) spectrum.

Flow Cytometers have grown from single parameter instruments to instruments that may have as many as 15 fluorescent parameters along with multiple light scatter and volume parameters. With the addition of each fluorescent parameter, an additional detector and data conversion channel along with the necessary light separation filter system is added. This has a significant impact on the cost of the instrument. The most expensive parts of the instrument are the light source, detectors, filters, and data conversion electronics.

Thus, there exists a need for more effective and less costly instrumentation for flow cytometers capable of detecting multiple wavelengths. The present invention satisfies this need and provides related advantages as well.

### SUMMARY OF THE INVENTION

The invention provides a device for analyzing the spectral content of a sample in a sequential manner at high speed.

### BRIEF DESCRIPTION OF THE DRAWINGS

FIG. 1 shows a schematic diagram of a flow cytometer showing a particle flowing through a sensing zone, where the particle is excited by a beam of light that then causes the particle to fluoresce and/or scatter light. The light is then separated by filters into portions of the electromagnetic (EM) spectrum and detected with photomultiplier tubes (PMT). The analog pulse is preprocessed and then digitized with an analog to digital converter (ADC).

FIG. 2 shows an exemplary embodiment of the invention. In this embodiment, the light emitting from the particle is separated into its spectral components with a prism or diffraction grating, and then a deflecting mechanism such as a high-speed mirror is used to sweep the rainbow of light across the photo detector. The output of the photo detector would then represent an analog optical spectrum of the particle's response to the excitation light source. A high speed ADC converts the detector output into a digital spectrum of the particles response to the excitation beam.

FIG. 3 shows an exemplary embodiment of the invention. In this embodiment, the light emitting from the particle is deflected so that the pathway entering the prism changes, which causes the output at one location on the prism to change its color as the input beam changes its angle.

FIG. 4 shows an exemplary embodiment of the invention. In this embodiment, a high-speed device that is capable of deflecting a specific wavelength of light away from the main beam of light at very high speed is used. If the light spectrum is scanned at high speed and the resulting deflected light is presented to the photo detector, the output of the detector would represent an optical spectrum of the particle's response to the excitation light source.

### DETAILED DESCRIPTION OF THE INVENTION

The present invention provides an apparatus and related methods for efficient detection of particles, for example, in a flow cytometer or other instruments such as confocal microscopes. It is the object of this invention is to take advantage of new analog to digital converters (ADC) technology, and use a serial processing scheme rather than the currently used parallel processing scheme. This will result in a reduction of parts, and an increase in the versatility of the analysis of particles.

The result of this configuration of elements is to produce a high-speed spectrum analyzer. One of the applications of this new technology is in the field of particle analysis such as the analysis of biological particles in a flow cytometer or a microscope. Other possible uses include, but are not limited to, confocal microscopes, chemical reaction monitoring, fluorescent decay analysis, and blood analyzers.

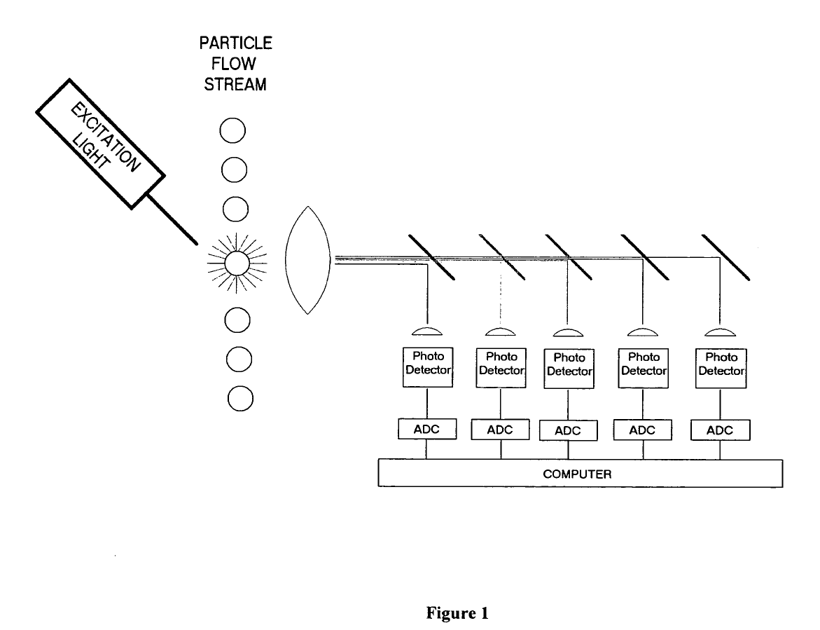

A flow cytometer is a device that flows a particle through a sensing zone where the particle is normally excited by a beam of light that then causes the particle to fluoresce and/or scatter light (see FIG. 1). The particles usually pass through the sensing zone in approximately 5 microseconds. The light is then separated by filters into portions of the EM spectrum, usually about 20 nm wide, and detected with a Photomultiplier Tube (PMT). The analog pulse is then preprocessed for its various values, for example, peak, width, integral, or log value, and then digitized with an analog to digital converter (ADC). Some systems digitize and then process the signal.

Flow Cytometers have grown from single parameter instruments to instruments that may have as many as 15 fluorescent parameters along with multiple light scatter and volume parameters. With the addition of each fluorescent parameter, an additional detector and data conversion channel along with the necessary light separation filter system is added. This has a significant impact on the cost of the instrument. The most expensive parts of the instrument are the light source, detectors, filters, and data conversion electronics.

Because of the 5-microsecond transit time of the particles in the excitation beam, parallel light processing schemes have been the only method of processing the light output. With the advent of high speed-high resolution Analog to Digital Converters (ADC), this is no longer true. It is now possible to sample at a rate of 2000 samples per microsecond with a resolution of 10 bits. The sampling rate and resolution of these ADCs are continuing to improve at a rapid pace. Although exemplified herein with ADCs, it is understood that other methods can be used, including any suitable data collection element to collect the spectral information, for example, a device that samples and holds data and can then collect data in parallel.

The invention is based on taking emitted light from a cell or particle illuminated by a beam of light, separating the emitted light into a rainbow of light, then sweeping that rainbow across an optical detector and digitizing the resulting output, resulting in a complete spectral analysis of the cell. The resolution of the analysis will be dependant on the width of the slit in front of the optical detector, the spread of the rainbow, and the speed of the digitizer. New high-speed digitizers and optical deflectors make it possible to make these measurements in the 1 micro second range.

The devices and methods of the invention are based on using a single optical detector coupled to a high-speed data conversion channel; separating the light into its individual spectral components; and presenting the separated spectral components individually to the photo detector at high speed.

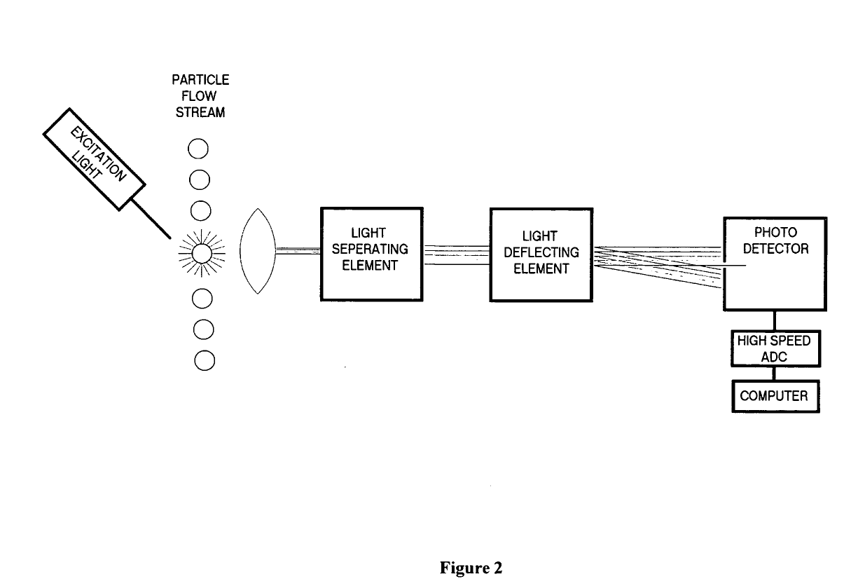

One embodiment of the invention is depicted in FIG. 2. In the embodiment depicted in FIG. 2, the light emitting from the particle is separated into its spectral components with a prism or diffraction grating, and then a deflecting mechanism such as a high-speed mirror is used to sweep the rainbow of light across the photo detector. The output of the photo detector represents an analog optical spectrum of the particle's response to the excitation light source. A high speed ADC converts the detector output into a digital spectrum of the particle's response to the excitation beam.

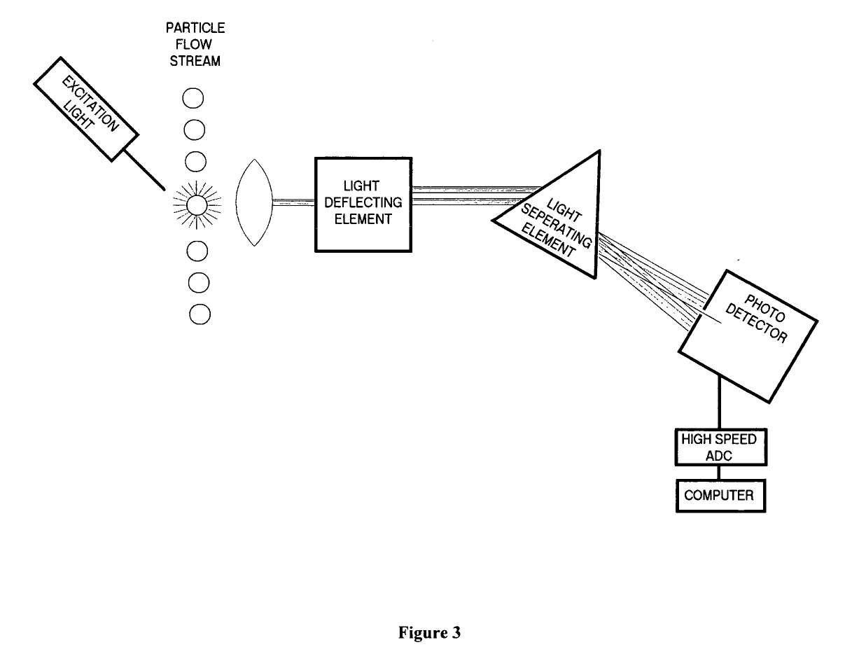

Another embodiment of the invention is depicted in FIG. 3. In the embodiment depicted in FIG. 3, the light emitting from the particle is deflected so that the pathway entering the prism changes, causing the output at one location on the prism to change its color as the input beam changes its angle.

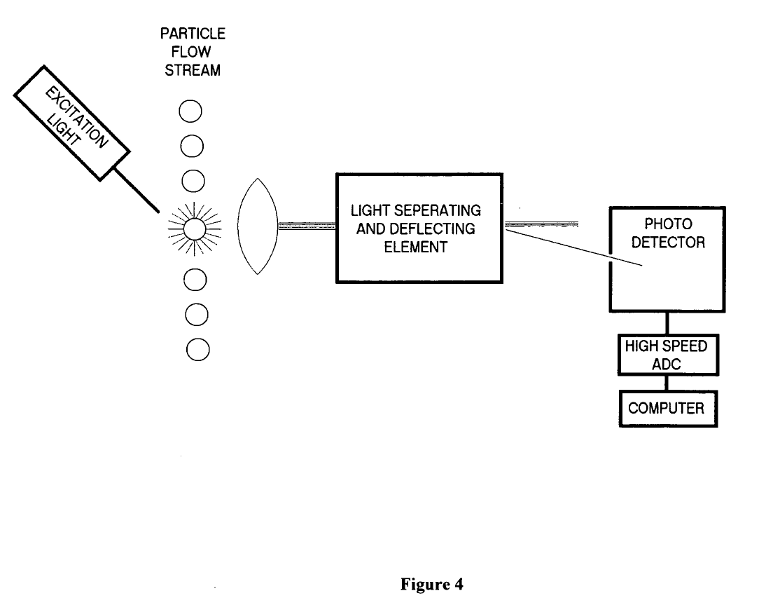

Yet another embodiment of the invention is depicted in FIG. 4. In the embodiment depicted in FIG. 4, a high-speed device that is capable of deflecting a specific wavelength of light away from the main beam of light at very high speed is used. If the light spectrum is scanned at high speed and the resulting deflected light is presented to the photo detector, the output of the detector represents an optical spectrum of the particle's response to the excitation light source.

The invention provides a device for analyzing the spectral content of a sample in a sequential manner at high speed and methods for using such a device. Such a device advantageously uses sequential, serial analysis rather than parallel analysis. Thus, the device analyzes the spectral content of a sample sequentially at high speed.

In one embodiment of a device of the invention, the spectral content of the sample is separated into a rainbow of light. Additionally in such a device, the rainbow of light is swept across a photo detector at high speed, producing a signal proportional to the spectral content of the sample. Further in such a device, the signal is processed with a high speed analog to digital converter (ADC) to produce a digital value for each component of the spectral content of the sample.

In another embodiment of a device of the invention, the spectral content of the sample is swept across the light-separating element, producing a high speed moving rainbow of light. Additionally in such a device, the moving rainbow of light is presented to a photo detector at high speed, producing a signal proportional to the spectral content of the sample. Further in such a device, the signal is processed with a high speed ADC to produce a digital value for each component of the spectral content of the sample.

In still another embodiment of a device of the invention, the spectral content of the sample is separated into individual portions of the spectrum at high speed and presented to a photo detector at high speed, for example, using an acousto-optic tunable filter (AOTF), producing a signal proportional to the spectral content of the sample. Additionally in such a device, the signal is processed with a high speed ADC to produce a digital value for each component of the spectral content of the sample.

The invention further provides a device for analyzing the spectral content of a sample sequentially at high speed as depicted in any of FIG. 2, 3 or 4. In a particular embodiment, the light separating element can be selected from a prism, a grating, and an acousto-optic tunable filter (AOTF). In another particular embodiment, the light deflecting element can be selected from a galvonic mirror, a rotating mirror, a micro-electromechanical system (MEMS) scanner, an acoustic-optic scanner, an electro-optic scanner, a KTN beam scanner, and a thin film optical waveguide. In still another particular embodiment, the light detecting element can be selected from a photo multiplier tube (PMT) and an avalanche photodiode (APD).

In yet another embodiment, the invention provides a device to analyze the spectral content of a sample in a sequential manner at high speed, wherein the spectral content of the sample is first separated into a rainbow of light. Then the rainbow of light is then swept across a photo detector at high speed, producing a signal proportional to the spectral content of the sample. The signal is then processed with a high speed ADC to produce a digital value for each component of the spectral content of the sample.

In still another embodiment, the invention provides a device to analyze the spectral content of a sample in a sequential manner at high speed, wherein the spectral content of the sample is first swept across the light-separating element, producing a high speed moving rainbow of light. The moving rainbow of light is then presented to a photo detector at high speed, producing a signal proportional to the spectral content of the sample. The signal is then processed with a high speed ADC to produce a digital value for each component of the spectral content of the sample.

In yet another embodiment, the invention provides a device to analyze the spectral content of a sample in a sequential manner at high speed, wherein the spectral content of the sample is separated into individual portions of the spectrum at high speed using a device such as an AOTF and presented to a photo detector at high speed, producing a signal proportional to the spectral content of the sample. The signal is then processed with a high speed ADC to produce a digital value for each component of the spectral content of the sample.

The invention additional provides methods of using any of the devices disclosed herein to analyze a sample. For example, the invention provides a method of analyzing a device using any of the devices depicted in FIG. 2, 3 or 4, or any other devices as disclosed herein.

The method of presenting the light to the detector can vary, as discussed above and contemplated by one skilled in the art. The serial nature of processing the light is advantageous in the devices and methods of the invention.

In still another embodiment, the invention provides a device for analyzing the spectral content of a sample of light in a sequential manner. The device can contain, for example, a light manipulating element configured to receive input light and generate a separated spectrum of light; a photo detector element configured to sequentially sample the separated spectrum of light and produce an output signal based on the separated spectrum of light; and a processor configured to process the output signal. In such a device, the light manipulating element can comprise a light separating element, configured to separate the input light into a spectrum of light; and a light deflecting element, configured to deflect the spectrum of light so as to sweep the spectrum of light across the photo detector, thereby forming the separated spectrum of light. The light separating element can be, for example, a prism, a grating, an OTF, and the like.

In addition, a device of the invention can have a light deflecting element such as a galvonic mirror, a rotating mirror, a MEMS scanner, an acoustic-optic scanner, an electro-optic scanner, a KTN beam scanner, or a thin film optical waveguide. Furthermore, a device of the invention can have a light manipulating element comprising a light deflecting element configured to deflect the input light; and a light separating element, across which the deflected input light is swept, configured to separate the deflected input light into the separated spectrum of light. In such a device, the light separating element can be, for example, a prism, a grating, or an AOTF. In addition, a device of the invention can have a light deflecting element such as a galvonic mirror, a rotating mirror, a MEMS scanner, an acoustic-optic scanner, an electro-optic scanner, a KTN beam scanner, a thin film optical waveguide, and the like. In a device of the invention, the photo detector element can be, for example, a PMT and an APD.

Examples of high speed ADC are shown in Table 1.

TABLE 1
High speed ADC.

| Meg samples/sec | Bits | Source | Type |
|---|---|---|---|
| 2000 | 10 | Delphi | modules |
| 400 | 12 | Acqiris | PCI card |
| 3000 | 8 | National | chip |
| 130 | 16 | Analog Devices | USB Module |
| 1500 | 8 | Maxim | chip |
| 250 | 12 | Maxim | chip |

Exemplary light separating elements include, for example, prisms, gratings, and acousto-optic tunable filter (AOTF), and the like.

Exemplary light deflecting elements include, for example, galvonic mirrors, rotating mirrors, micro-electromechanical systems (MEMS) scanners, acoustic-optic scanners, electro-optic scanners, KTN beam scanner, thin film optical waveguides, and the like.

A KTN beam scanner has been recently described by Nippon Telegraph and Telephone Corp. (NTT; Tokyo Japan) as being based on a newly discovered a novel phenomenon in which optical beam is steered by simply applying an electrical signal to an electro-optic crystal KTN (KTa₁₋ₓNbxO₃, Potassium Tantalate Niobate). The new found phenomenon has provided an electro-optic (EO) beam scanner with unprecedented performance, with the scanning efficiency of the KTN beam scanner being 80 times as high as the conventional EO beam scanner. The other features of the KTN beam scanner include wide scanning angle, high-speed response and compactness.

Exemplary light detecting elements include, for example, photo multiplier tube (PMT), avalanche photodiode (APD), and the like.

Although the invention has been described with reference to the examples provided above, it should be understood that various modifications can be made without departing from the spirit of the invention.

What is claimed is:

1. A device for analyzing the spectral content of a sample in a sequential manner at high speed.

2. The device of claim 1, wherein the spectral content of the sample is separated into a rainbow of light; the rainbow of light is swept across a photo detector at high speed, producing a signal proportional to the spectral content of the sample; and the signal is processed with a high speed analog to digital converter (ADC) to produce a digital value for each component of the spectral content of the sample.

3. The device of claim 1, wherein the spectral content of the sample is swept across the light-separating element, producing a high speed moving rainbow of light; the moving rainbow of light is presented to a photo detector at high speed, producing a signal proportional to the spectral content of the sample; and the signal is processed with a high speed ADC to produce a digital value for each component of the spectral content of the sample.

4. The device of claim 1, wherein the spectral content of the sample is separated into individual portions of the spectrum at high speed and presented to a photo detector at high speed, producing a signal proportional to the spectral content of the sample; and the signal is processed with a high speed ADC to produce a digital value for each component of the spectral content of the sample.

5. The device of claim 4, wherein the spectral content of the sample is separated into individual portions of the spectrum at high speed using an acousto-optic tunable filter (AOTF).

6. The device of claim 1, wherein the spectral content of the sample is separated into a rainbow of light.

7. The device of claim 6, wherein the rainbow of light is swept across a photo detector at high speed, producing a signal proportional to the spectral content of the sample.

8. The device of claim 7, wherein the signal is processed with a high speed ADC to produce a digital value for each component of the spectral content of the sample.

9. The device of claim 1, wherein the spectral content of the sample is swept across the light-separating element, producing a high speed moving rainbow of light.

10. The device of claim 9, wherein the moving rainbow of light is presented to a photo detector at high speed, producing a signal proportional to the spectral content of the sample.

11. The device of claim 10, wherein the signal is processed with a high speed ADC to produce a digital value for each component of the spectral content of the sample.

12. The device of claim 1, wherein the spectral content of the sample is separated into individual portions of the spectrum at high speed and presented to a photo detector at high speed, producing a signal proportional to the spectral content of the sample.

13. The device of claim 12, wherein the signal is processed with a high speed ADC to produce a digital value for each component of the spectral content of the sample.

14. The device of claim 13, wherein the spectral content of the sample is separated into individual portions of the spectrum at high speed using an acousto-optic tunable filter (AOTF).

15. A device for analyzing the spectral content of a sample sequentially at high speed as depicted in any of FIG. 2, 3 or 4.

16. The device of claim 15, wherein the light separating element is selected from a prism, a grating, and an acousto-optic tunable filter (AOTF).

17. The device of claim 15, wherein the light deflecting element is selected from a galvonic mirror, a rotating mirror, a micro-electromechanical system (MEMS) scanner, an acoustic-optic scanner, an electro-optic scanner, a KTN beam scanner, and a thin film optical waveguide.

18. The device of claim 15, wherein the light detecting element is selected from a photo multiplier tube (PMT) and an avalanche photodiode (APD).

19. A device for analyzing the spectral content of a sample of light in a sequential manner comprising:
a light manipulating element configured to receive input light and generate a separated spectrum of light;
a photo detector element configured to sequentially sample the separated spectrum of light and produce an output signal based on the separated spectrum of light; and
a processor configured to process the output signal.

20. The device of claim 19, wherein the light manipulating element comprises:
a light separating element, configured to separate the input light into a spectrum of light; and
a light deflecting element, configured to deflect the spectrum of light so as to sweep the spectrum of light across the photo detector, thereby forming the separated spectrum of light.

21. The device of claim 20, wherein the light separating element is selected from a group comprising: a prism, a grating, and an AOTF.

22. The device of claim 20, wherein the light deflecting element is selected from a group comprising: a galvonic mirror, a rotating mirror, a MEMS scanner, an acoustic-optic scanner, an electro-optic scanner, a KTN beam scanner, and a thin film optical waveguide.

23. The device of claim 19, wherein the light manipulating element comprises:
a light deflecting element configured to deflect the input light; and
a light separating element, across which the deflected input light is swept, configured to separate the deflected input light into the separated spectrum of light.

24. The device of claim 23, wherein the light separating element is selected from a group comprising: a prism, a grating, and an AOTF.

25. The device of claim 23, wherein the light deflecting element is selected from a group comprising: a galvonic mirror, a rotating mirror, a MEMS scanner, an acoustic-optic scanner, an electro-optic scanner, a KTN beam scanner, and a thin film optical waveguide.

26. The device of claim 19, wherein the photo detector element is selected from a group comprising: a PMT and an APD.
